(19) United States
(12) Patent Application Publication
(10) Pub. No.: US 2007/0205787 A1
(43) Pub. Date: Sep. 6, 2007

(54) Wafer holder, and heater unit and wafer prober provided therewith

(75) Inventors: Masuhiro Natsuhara, Itami-shi (JP); Tomoyuki Awazu, Itami-shi (JP); Hirohiko Nakata, Itami-shi (JP); Katsuhiro Itakura, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/701,416

(22) Filed: Feb. 2, 2007

(30) Foreign Application Priority Data
Feb. 21, 2006 (JP) 2006-043804

(51) Int. Cl. G01R 31/02

(52) U.S. Cl. 324/760

(57) ABSTRACT

A wafer holder with which probing can be performed with little or virtually no noise due to the wafer being shielded from electromagnetic waves; and a wafer prober on which the wafer holder is mounted. The wafer holder of the present invention includes a chuck top for mounting a wafer, and a resistance heat generator for heating the chuck top. At least part of the resistance heat generator is covered by an insulating layer, and an electrically conductive layer is present on an opposite side of the resistance heat generator having the insulating layer. The electrically conductive layer blocks electromagnetic waves that adversely affect inspection. The insulating layer preferably covers the entire surface of the resistance heat generator, and the electrically conductive layer preferably covers the entire surface of the resistance heat generator comprising the insulating layer.

### BACKGROUND OF THE INVENTION

1. Field of the Invention

The present invention relates to a wafer holder and a heater unit used in a wafer prober for mounting a semiconductor wafer on a wafer-mounting surface and pressing a probe card against the wafer to inspect the electrical characteristics of the wafer, and to a wafer prober on which the wafer holder and the heater are mounted.

2. Description of the Background Art

In the prior art, a heating procedure is performed in a semiconductor inspection step on a semiconductor substrate (wafer) to be treated. Specifically, the wafer is heated to a temperature higher than the normal operating temperature, potentially defective semiconductor chips are made to fail at an accelerated rate and are removed, and a burn-in is performed to prevent the occurrence of defects after shipping. In the burn-in step, after the semiconductor circuits are formed on the semiconductor wafer and before the wafer is diced into individual chips, the electrical characteristics of each chip are measured while the wafer is heated, and defective chips are removed. A strong demand has existed for the processing time to be reduced in the burn-in step in order to improve throughput.

In such a burn-in step, the semiconductor substrate is supported and heated using a heater. Since the entire reverse surface of the wafer must be in contact with a ground electrode, conventional heaters have been made of metal. A wafer on which circuits are formed is mounted on a metal flat-plate heater, and the electrical characteristics of the chips are measured. A measuring instrument called a probe card, which is provided with numerous electrically conductive electrode pins, is pressed onto the wafer with a force of tens to hundreds of kilograms-force when the measurements are made. Therefore, if the heater is thin, the heater may be deformed, causing contact failure to occur between the wafer and the probe pin. Therefore, the use of thick metal plates having a thickness of 15 mm or greater has been necessary in order to preserve the rigidity of the heater, and long periods are required for raising and lowering the temperature of the heater, which has become a large obstacle to improving throughput.

Additionally, in the burn-in step, electricity is applied to the chips, and the electrical characteristics are measured. However, with the increasing power output of chips in recent years, the chips generate large amounts of heat when the electrical characteristics are measured, and are sometimes damaged by the heat they generate. Rapid cooling after measurement has therefore been needed. Additionally, heating needs to be as uniform as possible during measurement. Copper (Cu), which has a high thermal conductivity of 403 W/mK, has therefore been used as the metal material.

Accordingly, in Japanese Laid-Open Patent Application Publication No. 2001-033484, a wafer prober is proposed wherein a thin metal layer and not a thick metal plate is formed on the surface of a thin but highly rigid ceramic substrate, resulting in minimized deformation and a low heat capacity. Since this wafer prober has high rigidity, contact failures do not occur. Since this wafer prober has low heat capacity, the temperature can be raised and lowered in a short time. Also disclosed is the use of an aluminum alloy, stainless steel or the like for the support member used to position the wafer prober.

However, if, as disclosed in Japanese Laid-Open Patent Application Publication No. 2001-033484, the wafer prober is only supported at the outermost periphery, the wafer prober may bend due to the pressure of the probe card. Therefore, measures such as providing a large number of support pillars or the like have been necessary.

Furthermore, with the scale of the semiconductor process decreasing over the past several years, a demand has arisen for increased load per unit area during probing and for precise alignment between the probe card and prober. The prober usually repeatedly performs an operation in which the wafer is heated to a predetermined temperature, and moved to a predetermined position during probing, whereupon a probe card is pressed on the wafer. In this case, high precision is also required in the drive system in order to move the prober to the predetermined position.

However, when the wafer is heated to a prescribed temperature; i.e., to about 100° C. to about 200° C., the heat is conveyed to the drive system, and problems have arisen in regard to a loss of precision due to thermal expansion of the metal components in the drive system. Furthermore, due to the increased load during probing, the wafer-holding prober itself must be rigid. Specifically, problems have been presented in that, if the prober itself deforms under load during probing, the pins of the probe card will not be able to make uniform contact with the wafer, thereby rendering inspection impossible, or, in the worst case, damaging the wafer. For this reason, probers are made larger in order to inhibit deformation, and problems have arisen in that the weight of the prober increases and the increased weight affects the precision of the drive system. A problem also arises in that as the size of the prober increases, much more time is required to increase or reduce the temperature of the prober, and throughput decreases.

Furthermore, very low current values are sometimes measured during the inspection of recent semiconductors. In such instances, the inspection of the semiconductor may be affected by electromagnetic waves that emanate from the resistance heat generator for heating the wafer or from electric equipment that is placed in the vicinity of the wafer.

### SUMMARY OF THE INVENTION

The present invention was devised in order to resolve the foregoing problems. Specifically, in a conventional wafer holder, a resistance heat generator that generates heat on being electrified is provided to the vicinity or interior of a chuck top in order to heat the chuck top to a predetermined temperature. However, when this resistance heat generator is used and the chuck top or a wafer is heated, the measurement of very low electric currents (electric currents at the picoampere (pA) level or lower) during inspection is affected by electromagnetic waves generated from the resistance heat generator. It is an object of the present invention to provide a wafer holder whereby probing can be performed with little or virtually no noise by shielding the wafer from electromagnetic waves generated from the resistance heat generator or the like; and to provide a wafer prober on which the wafer holder is mounted.

The wafer holder of the present invention comprises a chuck top for mounting a wafer, and a resistance heat generator for heating the chuck top. At least part of the resistance heat generator is covered by an insulating layer, and an electrically conductive layer is formed on the insulating layer. The electrically conductive layer blocks electromagnetic waves that adversely affect inspection. The insulating layer preferably covers the entire surface of the resistance heat generator; and the electrically conductive layer preferably covers the entire surface of the resistance heat generator comprising the insulating layer.

The electrically conductive layer is preferably mainly composed of iron or nickel. The total amount of iron and nickel contained in the electrically conductive layer is preferably 90 wt % or greater.

A heater unit comprising such a wafer holder and a wafer prober comprising the heater unit can reduce the effects of electromagnetic waves and other noise generated from the resistance heat generator and other devices.

According to the present invention, there can be provided a wafer holder and wafer prober whereby a very low electric current can be measured with little noise present by greatly reducing the amount of electromagnetic waves and other noise generated by the resistance heat generator and other devices during probing.

### BRIEF DESCRIPTION OF THE DRAWINGS

FIG. 1 shows an example of a cross-sectional structure of the wafer holder of the present invention;

FIG. 2 shows an example of a cross-sectional structure of the heat generator of the present invention;

FIG. 3 shows an example of a cross-sectional structure of the chuck top of the present invention; and

FIG. 4 shows another example of a cross-sectional structure of the wafer holder of the present invention.

### DETAILED DESCRIPTION OF THE INVENTION

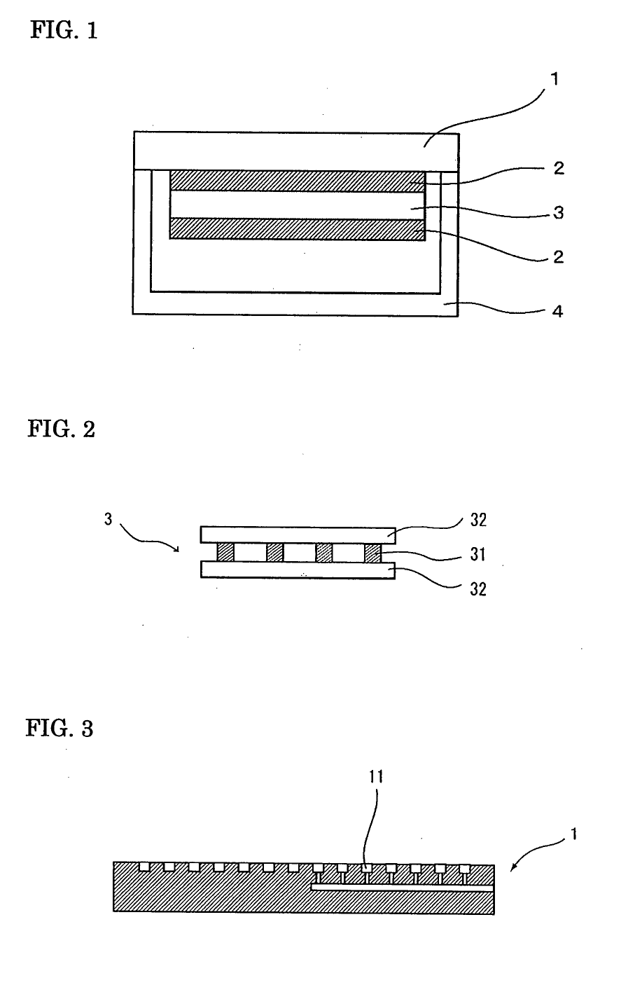

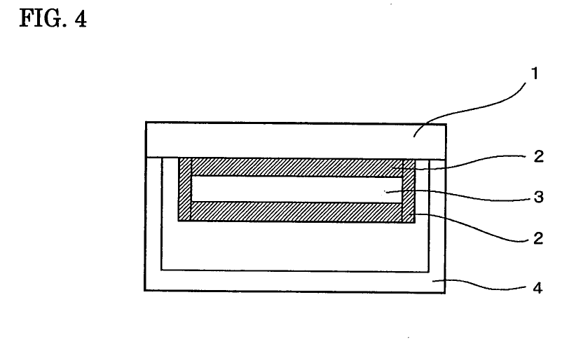

In the present invention, a resistance heat generator (heater) 3 on which an insulating layer is formed is provided to an opposite side of a wafer-mounting surface of a chuck top 1, and an electrically conductive layer 2 is formed on the resistance heat generator, as shown in FIG. 1. The electrically conductive layer may be formed on both sides of the resistance heat generator, or on only one of the sides, as shown in FIG. 1. An electrically conductive layer can also be formed on a side surface of the resistance heat generator as well as on both of the surfaces thereof, as shown in FIG. 4. If an electrically conductive layer is also formed on the side surface, the electromagnetic wave-blocking effect can be further increased.

The resistance heat generator 3 can be configured using a variety of structures. For example, the heat generator can be composed of a resistance heat generator 31 sandwiched by, e.g., mica or another insulator 32, as shown in FIG. 2, which is a simple structure and is therefore preferred. Metal materials can be used for the resistance heat generator. For example, a foil or the like made from nickel, stainless steel, silver, tungsten, molybdenum, chromium, or an alloy of these metals can be used as the resistance heat generator. Of these metals, stainless steel and Nichrome™ are preferable. Stainless steel or Nichrome™ can be used to form the circuit pattern of the resistance heat generator with relatively good precision by etching or other methods during the process of shaping the heat generator. These materials are also resistant to oxidation and inexpensive, and are therefore preferable in terms of withstanding usage for long periods of time even at high operating temperatures.

As long as the insulator that sandwiches the heat generator is heat-resistant, the composition thereof is not particularly limited. For example, silicone resins, epoxy resins, phenol resins, and the like may be used in addition to mica, as mentioned above. When the heat generator is sandwiched by such an insulating resin, a filler can be dispersed in the resin so that heat generated by the heat generator will be more evenly conveyed to the chuck top. The filler dispersed in the resin acts to increase the thermal conductivity of the silicone resin or other material. The composition of the filler is not particularly limited as long as the material does not react with the resin. Examples include boron nitride, aluminum nitride, alumina, and silica. The heat generator is screwed or otherwise mechanically fixed to a mounting part.

An electrically conductive layer is formed on the insulating layer in the resistance heat generator covered by the insulating layer. The electrically conductive layer will be very effective in shielding electromagnetic waves, provided that an electrically conductive material is used therefor. The electrically conductive layer can also cover part of the insulating layer rather than the entire surface, and can cover the surface in a mesh-form configuration. However, as has been particularly true over the past several years, probing is affected by even small quantities of electromagnetic waves, i.e., noise, for which reason the entire surface of the resistance heat generator is preferably covered by the electrically conductive layer. In view of these circumstances, the material used for the electrically conductive layer is preferably a material having high magnetic permeability. Specifically, the material is preferably an alloy of iron, nickel, or another metal, or such an alloy doped with cobalt or molybdenum. Covering the resistance heat generator with such a material allows electromagnetic waves generated by the resistance heat generator to be substantially blocked. Connecting a grounding line to the electrically conductive layer will allow almost all electromagnetic waves to be blocked, and is therefore preferable. As long as the total amount of iron and nickel contained in the electrically conductive layer is 90 wt % or greater, the electromagnetic characteristics will be exceptional and noise will be blocked regardless of whether the power source applied to the resistance heat generator is an alternating current or a direct current.

There are no particular limitations regarding the method for forming the electrically conductive layer. However, the electrically conductive layer can be formed on the insulating layer by sputtering or vapor deposition, or the metal can be made into a foil and used to cover the insulating film. This allows electromagnetic waves generated from the resistance heat generator to be blocked. A wafer holder provided with such functionality can also favorably be used in a wafer prober for measuring very low electric currents.

The resistance heat generator may be formed on the chuck top or the cooling module (described hereunder) by screen printing or another method. In such instances, when the chuck top and cooling module are not insulators, the heat generator may be formed after an insulating layer made of glass or another material has been formed on the surface on which the heat generator is to be formed. There are no particular limitations regarding the material of the heat generator. Examples of materials that can be used include silver, platinum, palladium, and alloys and mixtures thereof.

Once the electrically conductive layer has been formed by vapor deposition, or a metallic foil is used so as to cover the substrate on which the resistance heat generator is formed, a chuck top substrate may be formed once again on the electrically conductive layer. However, the resulting structure will be somewhat complex.

There are no particular limitations regarding the material used for the chuck top. However, a material having high thermal conductivity, i.e., 15 W/mK or greater, is preferred in order to improve the heating uniformity of the wafer-mounting surface. If the thermal conductivity is less than 15 W/mK, the temperature distribution of the wafer mounted on the chuck top will be poor, which is undesirable. If the thermal conductivity is 15 W/mK or greater, the resulting heating uniformity will pose no hindrance to probing. Alumina of 99.5% purity (30 W/mK thermal conductivity) is an example of a material with such thermal conductivity. The thermal conductivity is particularly preferably 170 W/mK or greater. Aluminum nitride (170 W/mK) and Si—SiC complexes (170 W/mK to 220 W/mK) are examples of materials having such thermal conductivity. The chuck top will have extremely good heating uniformity if the thermal conductivity is at this level.

Metals can also be used for the chuck top of the present invention. In addition to the abovementioned materials, copper, aluminum, nickel, stainless steel, tungsten, molybdenum, and other metals can be used for this purpose.

The chuck top holds the wafer via a vacuum chuck. Therefore, a process must be performed to form grooves in the chuck or to perform a process in which the flatness, surface roughness, and other aspects of the wafer-mounting surface are controlled. The flatness is preferably 50 μm or less and the surface roughness Ra is preferably 0.1 μm or less. Examples of materials that satisfy these conditions include materials mainly composed of copper, aluminum, or another metal; and metal/ceramic complexes created by adding silicon carbide or aluminum nitride to the abovementioned metals. If a metallic layer must be formed on the wafer-mounting surface of the chuck top, the metallic layer can be formed by plating using nickel, gold, or the like; vapor deposition; sputtering; or another method.

A conducting layer is formed on the wafer-mounting surface of the chuck top in order to protect the mounting stage from corrosive gasses, acids, alkali chemicals, organic solvents, water, and other substances commonly used in semiconductor manufacturing processes; and to prevent electromagnetic noise originating below the mounting stage from entering the space below the wafer mounted on the mounting stage. The conducting layer therefore acts as a grounder.

There are no particular limitations regarding the method used to form the conducting layer. Examples of methods include applying a conductive paste by screen printing and then firing the resulting material, as well as vapor deposition, sputtering, spraying, plating, or another method. Among these methods, spraying and plating are particularly favorable. No heat treatment is performed when the conducting layer is formed with these methods. Therefore, the mounting stage will not warp due to a heat treatment, and the cost is relatively low, resulting in an inexpensive conducting layer having exceptional characteristics. Plated films in particular are denser and have higher electrical conductivity than sprayed films, and are therefore especially preferable. Nickel and gold are examples of materials that are used in plating and spraying. These materials have relatively high electrical conductivity and exceptional resistance to oxidation, and are therefore preferable.

The surface roughness Ra of the conducting layer is preferably 0.5 μm or less. If the surface roughness exceeds 0.5 μm, then when an element having a high heating value is measured, the heat generated by the element itself during probing will be impossible to disperse from the conducting layer or mounting stage, the temperature of the element will increase, and thermal fracturing may occur. A surface roughness Ra of 0.02 μm or less allows for the efficient dispersal of heat, and is therefore preferable.

A plating film composed of, e.g., copper, gold, or silver, which have high electrical conductivity, can also be formed on the chuck top. A plating film that is, e.g., 100 μm thick or greater will allow the temperature distribution on the mounting surface to be made relatively uniform, and is therefore preferable. In such instances, the above-described copper, gold, or silver plating layer can be formed after, e.g., a nickel plating has been formed in order to preserve the adhesion between the chuck top and the plating film formed on the chuck top. Gold plating can also be applied after, e.g., a highly electrically conductive copper plating film has been formed in order to impart anti-oxidation characteristics and chemical resistance.

The plating film preferably has a thickness of 100 μm or more in order to improve heating uniformity. If the plating thickness is less than 100 μm, the effect of making the temperature of the wafer-mounting surface more uniform will deteriorate. There is no particular upper limit to the thickness of the plating film. Once the plating film has thus been formed, a groove or holes for suctioning the wafer can be formed, and a wafer-mounting surface can be formed by grinding the mounting surface. In such a process, the depth of the grooves on the holding member can be reduced by an amount corresponding to the thickness of the plating in order to process the mounting surface, and, in particular, in order to process the wafer-mounting surface. Therefore, the surface can be processed less expensively than when the chuck top itself is processed. The plating film is preferably thicker than the depth of the grooves.

Copper, gold, or silver, which have high thermal conductivity, can also be formed on the chuck top as a sprayed film. The film in such instances preferably has a thickness of 100 μm or more, as with the above-described plating. Spraying allows the mounting surface to be processed inexpensively, as with plating, and is therefore preferable. It shall be apparent that plating and spraying can also be combined.

There are no particular limitations regarding the method for mounting the wafer. However, with a wafer prober, typically, concentric grooves 11 are formed on the chuck top, and vacuum chucking is performed using the grooves, as shown in FIG. 3. Such a wafer holder also has an exceptional cooling rate.

The wafer holder of the present invention can have a support 4 for supporting the chuck top 1, as shown in FIG. 1. In particular, the presence of a support is preferable when the wafer holder of the present invention is used for a wafer prober. In other words, the support in such instances acts to prevent heat generated by the heat generator from being transferred to the driving part; i.e., the support ensures positional accuracy. For this reason, the thermal conductivity of the support is preferably 40 W/mK or less. If the thermal conductivity of the support exceeds 40 W/mK, heat applied to the chuck top will be readily transferred to the support, and the precision of the drive system will be affected, which is undesirable.

Since high temperatures of 150° C. or greater are currently required when probing is performed, the support preferably has a thermal conductivity of 10 W/mK or less. A thermal conductivity of 5 W/mK or less is even more preferable. The reason is that if the thermal conductivity is of such a level, the amount of heat transmitted from the support to the drive system will dramatically decrease.

The Young's modulus of the support is preferably 200 GPa or greater. If the Young's modulus of the support is less than 200 GPa, the holder itself may deform, which is undesirable. A heat-insulating effect cannot be expected. A Young's modulus of 300 GPa or greater is even more preferable. If the material has a Young's modulus of 300 GPa or greater, deformation of the support can be dramatically reduced, allowing the support to be made smaller and lighter, which is especially preferable.

Mullite, alumina, and complexes of mullite and alumina (mullite-alumina complexes) are preferably used as support materials that satisfy such conditions. Mullite has low thermal conductivity and a high heat-insulating effect, and is therefore preferable. Alumina has a high Young's modulus and high rigidity, and is therefore preferable. Mullite-alumina complexes have a thermal conductivity that is lower than that of alumina, and a Young's modulus that is higher than that of mullite, and are therefore preferable overall.

There are no particular limitations regarding the shape of the support as long as the structure supports the outer or inner periphery of the chuck top and does not lead to warping of the chuck top.

A cooling module can be disposed on the lower part of the chuck top. The cooling module is used when the wafer and chuck top are to be cooled or when an operation is to be performed at or below normal temperatures.

The cooling module may be moveable or fixed to the chuck top. With a moveable cooling module, the temperature can efficiently be increased in a short time for heating purposes by separating the cooling module from the chuck top; and, for cooling purposes, the cooling module is brought into contact with the chuck top to achieve rapid cooling. The method for making the cooling module move may employ an air cylinder, hydraulic device, or other raising/lowering means, and is not particularly limited. Using a moveable cooling module is preferred since the cooling rate will dramatically improve and throughput will increase without a reduction in the rate of temperature increase in the wafer and chuck top. Such a method is also preferable in that the cooling module will not deform under pressure from the cooling module because the probe card does not exert any pressure on the cooling module during probing; and the cooling performance is greater than that of air cooling, in which cool air is blown on the chuck top.

If the rate at which the wafer and chuck top are cooled is of greater importance, the cooling module may be fixed to the chuck top. If the wafer holder is used at a temperature lower than normal temperature, fixing the cooling module to the chuck top will result in more effective cooling, and is therefore preferable. A deformable and heat-resistant flexible material having high thermal conductivity can also be inserted between the chuck top and cooling module. By providing a flexible material that allows the degree of flatness and warping to be alleviated between the chuck top and cooling module with respect to each other, the contacting area can be widened further, and the cooling performance of a cooling module as an essential component can be further demonstrated. The cooling rate can therefore be increased. Examples of materials that can be used as the flexible material include silicon, epoxy, phenol, polyimide, and other heat-resistant materials; materials obtained by dispersing BN, silica, AlN, or another filler in the abovementioned resins in order to improve thermal conductivity; and foamed metals.

There are no particular limitations regarding the method for fixing the cooling module. For example, the cooling module can fixed using a mechanical technique such as screwing or clamping. When the chuck top and cooling module are fixed via screwing, the use of three or more screws or even six or more screws will increase adhesion between the members and further improve the cooling capacity, and is therefore preferable. In the present structure, the holding member and cooling module are fixed; therefore, a higher cooling rate can be achieved in comparison to when the members are moveable.

The chuck top and cooling module can also be integrated. There are no particular limitations regarding the materials used for the holding member and cooling module when the members are integrally formed. However, a flow channel through which a coolant is circulated must be formed in the cooling module, for which reason the difference between the thermal expansion coefficients of the chuck top and cooling module is preferably small, and, as shall be apparent, the components are preferably composed of the same material.

When the chuck top and cooling module are integrated, the abovementioned ceramic materials and ceramic/metal complexes can be used as the materials for the holding member. A flow channel for cooling is formed on a surface of the chuck top opposite the wafer-mounting surface. A chuck top with which a cooling module has been integrated can be fabricated by integrating a substrate composed of the same material as the chuck top via brazing, glass bonding, or another technique. As shall be apparent, the flow channel may be formed on the substrate of the attaching side, or on both substrates. The chuck top and cooling module can also be integrated by being screwed together. In such instances, a configuration must be devised in which the coolant or the like is prevented from flowing out from the resulting flow channel by using an O-ring or the like.

Integrating the chuck top and cooling module thus allows the wafer, mounting stage, and holding member to be cooled more quickly than when the chuck top and cooling module are fixed in the above-described manner.

Another conducting layer can be formed on the surface of the wafer mounting surface in instances where the chuck top is composed of a metal, where the surface readily oxidizes or deteriorates, or where electrical conductivity is low. The layer can be formed by plating nickel or another oxidation-resistant material, or by combining plating and spraying in the above-described manner.

There are no particular limitations regarding the material of the cooling module. Aluminum, copper, and alloys thereof are preferred for their relatively high thermal conductivity, which allows the heat of the chuck top to be dispersed rapidly. A stainless steel, magnesium alloys, nickel, or another metal material can also be used. In addition, an oxidation-resistant metal film made from nickel, gold, or silver can be plated, sprayed, or otherwise formed on the cooling module in order to impart the cooling module with oxidation-resistance.

A ceramic material can also be used for the cooling module. There are no particular limitations regarding such a material. However, aluminum nitride and silicon carbide are preferable because of their relatively high thermal conductivity, which allows heat to be dispersed quickly from the chuck top. Silicon nitride and aluminum oxynitride have high mechanical strength and exceptional durability, and are therefore preferable. Alumina, cordierite, steatite, and other oxide ceramic materials are relatively inexpensive and therefore preferable. A variety of materials can thus be selected for the cooling module. Therefore, a material may be selected according to the application. Nickel-plated aluminum and nickel-plated copper are preferred among these materials for their exceptional resistance to oxidation, high thermal conductivity, and relatively low cost.

A coolant may also be circulated through the cooling module. Heat transmitted to the cooling module is thereby rapidly removed from the cooling module, which improves the rate at which the wafer holder is cooled, and is therefore preferable. Coolant must be circulated when the chuck top is used at a temperature lower than normal temperature. There are no particular limitations regarding the coolant circulated within the cooling module. Examples of coolants that can be selected include water and Fluorinert™. However, water is ideal when taking into account the magnitude of specific heat and cost. Liquid coolant may leak from the device, for which reason gasses such as nitrogen and atmospheric gas can also be circulated.

In a preferred example, two aluminum plates are prepared and a flow channel is machined or otherwise formed in one of the aluminum plates for use in circulating the coolant. The entire surface of the aluminum plate is plated with nickel in order to improve resistance to corrosion and oxidation. The other nickel-plated aluminum plate is then affixed together therewith. An O-ring or the like is inserted into the circumference of the flow channel in order to prevent the coolant from leaking out. The two aluminum plates are screwed or welded together.

Alternatively, two copper (oxygen-free copper) plates are prepared and a flow channel for circulating water is machined or otherwise formed in one of the copper plates. The other copper plate is simultaneously joined via brazing to a stainless steel pipe that acts as an inlet and outlet for the coolant. The entire surface of the joined cooling plate is plated with nickel in order to improve resistance to corrosion and oxidation. Additionally, as a separate aspect, a cooling module can be obtained by mounting a coolant-conveying pipe to a cooling plate composed of aluminum, copper, or another metal. A groove having a shape similar to the cross section of the pipe may be formed on the cooling plate, and the cooling efficiency can be further increased by affixing the pipe thereto. A resin, ceramic material, or other thermally conductive material may also be inserted as an intermediate layer in order to improve adhesion between the cooling pipe and the cooling plate.

In addition, a pipe composed of copper or another metal can be mounted on a plate having high thermal conductivity composed of aluminum, copper, or the like; and the coolant can be circulated through the pipe. There are no particular limitations regarding the method for mounting the pipe to the plate. Examples of techniques include brazing and screwing using metal bands. The plate can be counter-sunk and a pipe mounted in the resulting hole to increase the area of contact between the pipe and plate and improve cooling efficiency. A thermally conductive sheet can also be inserted between the pipe and plate to improve cooling efficiency.

The surface of the support for supporting the mounting stage preferably has a heat-insulation structure. A notched groove is formed in the support member and the contact area between the chuck top and support is reduced, thereby forming such a heat-insulation structure. Such a structure can also be obtained by forming a notched groove in the chuck top. In such instances, the chuck top must have a Young's modulus of 200 GPa or greater. Specifically, pressure is applied to the chuck top by the probe card. Therefore, materials having a small Young's modulus will undergo dramatic deformation if a notch is present, which may lead to damage to the wafer or chuck top. However, if a notch is formed in the support, such problems do not occur, which is preferable. The notch may be formed as concentric or radial grooves, multiple protuberances, or another configuration without particular limitation. However, symmetry must be maintained regardless of the shape used. If the shape is not symmetrical, the pressure applied to the chuck top will be impossible to disperse uniformly, and the chuck top will be subjected to deformation, damage, or other problems, which is undesirable.

A plurality of pillar members are preferably disposed between the chuck top and the support member as an aspect of a heat-insulation structure. Preferably, eight or more pillar members are evenly positioned in a concentric or similar arrangement. In particular, wafers have increased to sizes of 8 to 12 inches over the past several years; therefore, a smaller number of pillar members will particularly result in greater distances therebetween. Accordingly, warping between the pillar members will more readily occur when the pins of the probe card are pressed on the wafer mounted on the chuck top, which is undesirable. When the area over which contact is made with the chuck top is the same as when an integrated structure is used, interfaces can be formed between the chuck top and the pillar members and between the pillar members and the support member. The interfaces will therefore become a heat-resistant layer, and the heat-resistant layer can be increased by a factor of two, making it possible to efficiently insulate heat generated by the chuck top. The pillar members may assume the configuration of a cylinder, triangular prism, quadrangular prism, another polygonal prism, or a pipe, without particular restriction. Regardless of the configuration, the insertion of pillar members in this manner makes it possible to block heat emitted by the chuck top toward the support.

The materials of the pillar members used in the heat-insulation structure above preferably have a thermal conductivity of 30 W/mK or less. If the thermal conductivity is higher than 30 W/mK, the thermal insulation effect deteriorates, which is undesirable. Examples of materials that can be used for the pillar members include Si₃N₄; mullite; mullite-alumina complexes; steatite; cordierite; stainless steel; glass (fiber); polyimide, epoxy, phenol, and other heat-resistant resins; and complexes of any of the above.

The parts of the support member and the chuck top or the pillar members that come into contact preferably have a surface roughness Ra of 0.1 μm or greater. If the surface roughness Ra is less than 0.1 μm, the contact area between the support member and the chuck top or pillar member will increase and gaps between the parts will become relatively small. The volume of transmitted heat will therefore be larger than when the Ra is 0.1 μm or greater, which is undesirable. There is no particular upper limit regarding the surface roughness; however, if the surface roughness Ra is 5 μm or greater, surface processing will become more expensive. Grinding, sand blasting, or other treatments are preferably used to obtain a surface roughness Ra of 0.1 μm or greater. However, the appropriate grinding and blasting conditions must be used in order to restrict the Ra to 0.1 μm or greater. The heat-insulation structure can also be formed between the support member and a stand. In any configuration, effective heat insulation can be obtained by using such a structure.

Mounting a wafer holder of the above description on a wafer holder for use in wafer inspection will result in a device that has exceptional heat uniformity and thermal insulation, and is inexpensive, which is therefore preferable.

### WORKING EXAMPLE 1

An Si—SiC complex having a diameter of 310 mm and a thickness of 10 mm was processed into the shape shown in FIG. 3. The surface was plated with nickel, and the wafer-mounting surface was ground, resulting in an Ra of 0.1 μm or less. A stainless steel foil having a thickness of 50 μm was sandwiched by a silicone resin in which BN powder had been dispersed to form a heat generator. The metallic foils shown in Table 1 and stainless steel foil were then provided to the surface of the heat generator. The electrically conductive layer was then grounded.

TABLE 1

| | Iron content (%) | Nickel (%) | Molybdenum (%) | Other (%) |
|---|---|---|---|---|
| 1 | 45 | 55 | | |
| 2 | 40 | 50 | 10 | |
| 3 | 20 | 75 | | Copper: 5 |
| 4 | 15 | 70 | 5 | Copper: 10 |
| 5 | | | 80 | Copper: 20 |

100 μm-thick metallic foils made of the materials shown in Table 1 were placed in positions shown in Table 2 for use as a wafer holder. In Table 2, “entire surface of the heat generator” refers to a configuration in which the electrically conductive layer was placed on a side surface of the heat generator in addition to the top and bottom, as shown in FIG. 4. Low electric current probing was performed at 150° C. using the wafer holder. Alumina was used for the support. The results of the probing are shown in Table 2. ⊚ indicates that no noise was generated and favorable probing was possible; ◯ indicates that noise had a slight effect, but that relatively favorable probing was possible; Δ indicates that noise was generated, but that probing was possible; and × indicates that noise was generated to a great extent and probing was hindered.

TABLE 2

| | | | Probing |
|---|---|---|---|
| | Material | Position | results |
| A | 1 | Entire surface of the heat generator | ⊚ |
| B | 1 | Top and bottom surfaces of the heat generator | ⊚ |
| C | 2 | Entire surface of the heat generator | ⊚ |
| D | 2 | Top and bottom surfaces of the heat generator | ⊚ |
| E | 3 | Entire surface of the heat generator | ⊚ |
| F | 4 | Entire surface of the heat generator | ⊚ |
| G | 4 | Top and bottom surfaces of the heat generator | ◯ |
| H | 5 | Entire surface of the heat generator | Δ |
| I | Stainless | Entire surface of the heat generator | Δ |
| | steel | | |
| J | None | None | X |
| K | 1 | Only the chuck top side of the heat generator | ◯ |
| L | 1 | Only the support-side of the heat generator | Δ |
| M | 2 | Only the chuck top side of the heat generator | ◯ |
| N | 3 | Only the chuck top side of the heat generator | ◯ |
| O | 4 | Only the chuck top side of the heat generator | Δ |
| P | 5 | Only the chuck top side of the heat generator | X |

It can be concluded from the above results that probing can be performed without any difficultly, depending on the material of the electrically conductive layer, if the electrically conductive layer is placed over the entire surface of the heat generator. In addition, when the electrically conductive layer is placed over only one side of the heat generator, probing will be performed more favorably if the electrically conductive layer is placed on the chuck top side of the heat generator.

According to the present invention, electromagnetic waves and other noise generated from a resistance heat generator or the like is dramatically reduced during probing, whereby it is possible to provide a wafer holder and wafer prober that are capable of measuring very low electrical currents with little noise.

What is claimed is:

1. A wafer holder comprising:
a chuck top configured and arranged to mount a wafer;
a resistance heat generator configured and arranged to heat the chuck top;
an insulating layer covering at least part of the resistance heat generator; and
an electrically conductive layer formed on the insulating layer.

2. The wafer holder according to claim 1, wherein
the insulating layer covers the entire surface of the resistance heat generator, and
the electrically conductive layer covers the entire surface of the insulating layer covering the resistance heat generator.

3. The wafer holder according to claim 1, wherein
the electrically conductive layer is mainly composed of iron or nickel.

4. The wafer holder according to claim 1, wherein
the electrically conductive layer is composed of at least iron and nickel with the total amount of iron and nickel contained in the electrically conductive layer being 90 wt % or greater.

5. A heater unit comprising the wafer holder according to claim 1.

6. A wafer prober comprising the heater unit according to claim 5.
